(19) United States
(12) Patent Application Publication
(10) Pub. No.: US 2007/0054420 A1
(43) Pub. Date: Mar. 8, 2007

(54) Substrate structure and method for wideband power decoupling

(75) Inventors: Chee Wai Albert Lu, Singapore (SG); Boon Keng Lok, Singapore (SG)

Correspondence Address: Hugh R. Kress;Browning Bushman P.C., Suite 1800, 5718 Westheimer, Houston, TX, 77057, US

(73) Assignee: Agency for Science, Technology and Research

(21) Appl. No.: 11/220,131

(22) Filed: Sep. 6, 2005

(51) Int. Cl. H01L 21/00

(52) U.S. Cl. 438/3

(57) ABSTRACT

A substrate structure and method of wideband power decoupling comprising one or more embedded capacitors each comprising a ferroelectric material.

### FIELD OF INVENTION

The present invention relates broadly to a substrate structure and method for wideband power decoupling.

### BACKGROUND

A typical power distribution network for power decoupling in electronic appliances and systems comprises of three core power decoupling components: low frequency bulk decoupling (μF to mF), mid frequency decoupling (μF) and high frequency decoupling (nF). The high frequency decoupling is typically implemented either on-chip (but limited by chip area) or as embedded capacitor(s). The mid frequency decoupling is typically implemented as embedded capacitor(s) or in the form of discrete capacitor(s). The low frequency bulk decoupling is typically implemented in the form of discrete capacitor(s).

Different techniques have been proposed for the implementation of substrate structures with embedded capacitors for power decoupling in electronic appliances and systems. These conventional approaches have limitations, including:
i) Integration with power distribution networks not being optimised for performance such as decoupling bandwidth,
ii) The lack of consideration of integration with discrete passive and active components,
iii) Limitations on manufacturing to specific process technologies,
iv) Non-optimal space utilization.

It is therefore desirable to provide a method and substrate structure for wideband power decoupling that overcomes or ameliorates one or more of the above mentioned limitations. It is further desirable to provide a method of forming such a substrate structure.

### SUMMARY

In accordance with a first aspect of the present invention there is provided a substrate structure for wideband power decoupling comprising one or more embedded capacitors each comprising a ferroelectric material.

The capacitors may comprise an ultra-thin film of the ferroelectric material of a thickness of less than about 1 μm.

The capacitors may comprise a film of the ferroelectric material formed with thick-film material processing or laminates of a thickness of about 1 μm to about 20 μm.

Properties of the respective ferroelectric materials may be selected such that said respective ferroelectric materials exhibit desired relaxation frequencies.

Respective capacitors may each comprise one or more electrodes of resistive material.

The materials of the electrodes may be selected such that the substrate structure exhibits a desired power decoupling resonance damping property.

The substrate structure may further comprise multi-layer interconnects for signal and power distribution.

The substrate structure may further comprise one or more discrete capacitors.

The substrate structure may further comprise one or more active devices and one or more interconnects to the respective active devices.

One or more electrodes of the capacitors may be electrically connected to a power plane of the substrate structure.

One or more electrodes of the capacitors may be electrically connected to a ground plane of the substrate structure.

In accordance with a second aspect of the present invention there is provided a substrate structure for wideband power decoupling comprising one or more embedded capacitors each comprising a ground electrode, a power electrode; and a ferroelectric material layer between the ground and power electrodes.

In accordance with a third aspect of the present invention there is provided a method of forming a substrate structure for wideband power decoupling, the method may comprise forming one or more embedded capacitors in the substrate structure, wherein each capacitor comprises a ferroelectric material.

The capacitors may comprise an ultra-thin film of the ferroelectric material of a thickness of less than about 1 μm.

The capacitors may be formed with a film of the ferroelectric material formed with thick-film material processing or laminates of a thickness of about 1 μm to about 20 μm.

Properties of the respective ferroelectric materials may be selected such that said respective ferroelectric materials exhibit desired relaxation frequencies.

Respective capacitors may be each formed with one or more resistive material electrodes.

Materials of the electrodes may be selected such that the substrate structure exhibits a desired power decoupling frequency damping property.

The method may further comprise forming multi-layer interconnects of the substrate structure for signal and power distribution.

The method may further comprise providing one or more discrete capacitors as part of the substrate structure.

The ferroelectric material may be deposited utilising hydrothermal synthesis.

Electrodes of the capacitors may be formed utilising thin-film processes.

A first electrode of the respective capacitors may be formed utilising, but not limited to, thin-film processes, and a second electrode of the respective capacitors may be formed utilising thick-film processes.

The method may further comprise a processing step for increasing the robustness of the as-formed ferroelectric material.

The processing step may comprise post deposition plasma processing, thick-film processing, or both.

In accordance with a fourth aspect of the present invention there is provided a method of forming a substrate structure for wideband power decoupling, the method comprising forming a first electrode; forming a ferroelectric material layer on the first electrode; and forming a second electrode on the ferroelectric layer; wherein the first electrode, the second electrode and the ferroelectric material layer form an embedded capacitor in the substrate structure.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 shows plots of impedance versus frequency, illustrating a performance comparison of conventional capacitors and capacitors according to embodiments of the present invention.

FIG. 2 shows a schematic cross-sectional view of a substrate structure according to an embodiment of the present invention.

FIG. 3 shows an equivalent circuit for conventional power decoupling.

FIG. 4 shows an equivalent circuit for power decoupling according to an example embodiment of the present invention.

FIG. 5 is a schematic cross sectional view of a substrate structure according to an example embodiment of the present invention.

FIG. 6 shows a flow chart illustrating a method of fabricating a substrate structure in accordance with an example embodiment of the present invention.

### DETAILED DESCRIPTION

Embodiments of the invention described herein provide a substrate structure for wideband power decoupling using ultra-thin ferroelectric capacitor dielectric materials.

As will be appreciated by those skilled in the art, the power distribution impedance, Z, for power decoupling in electronic appliances and systems where the resistance is negligible, is defined by the equation

$$Z = \frac{1}{jω {C}_{0}} \qquad ( 1 )$$

where C₀ is the nominal dielectric constant and ω is the frequency.

Equation (1) is, however, only valid at low frequencies below self-resonance. The self-resonant frequency in conventional power distribution systems with paraelectric capacitors, i.e. frequency stable capacitors, is determined by the parasitic inductance. The self-resonant frequency ω₀ is defined by the equation:

$${ω}_{0} = \sqrt{\frac{1}{{L}_{0} {C}_{0}}} \qquad ( 2 )$$

where L₀ is the effective nominal parasitic inductance.

It is important to note that the effective parasitic inductance value cannot be infinitely small but would typically be in the order of greater than 100 pH. Therefore, a capacitor with a relatively higher capacitance value reduces low frequency impedance but also results in a lower self-resonant frequency. The conventional approach is to use a large number of capacitors each having a small capacitance value to increase the self-resonant frequency whilst reducing the effective inductance. Hence, conventional designs typically use a large number of capacitors.

In a ferroelectric material, the dielectric constant typically changes significantly at the relaxation frequency ω₁. As will be appreciated by those skilled in the art, the high frequency relaxation phenomenon has been attributed to piezoelectric resonance of grains and domains, inertia to domain wall movement, and the emission of GHz shear waves from ferroelastic domain walls.

The dielectric constant for a ferroelectric material varies inversely proportionally to frequency ω during the relaxation phase, resulting in a varying capacitance C. An example of a first-order approximation during relaxation is given by the following equation:

$$C = \frac{{ω}_{1} {C}_{0}}{ω} , valid for frequency ω > {ω}_{1} \qquad ( 3 )$$

The resultant self-resonant frequency ωᵣₑₛ is actually increased, as defined in the following equation:

$${ω}_{res} = {ω}_{0} \frac{{ω}_{0}}{{ω}_{1}} \qquad ( 4 )$$

when the relaxation frequency is below the otherwise nominal self-resonant frequency.

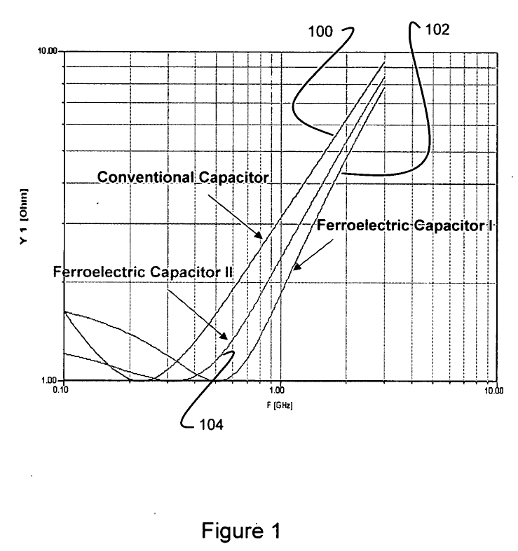

An example of the performance comparison of conventional capacitors and ferroelectric capacitors in example embodiments of the invention is shown in FIG. 1. In this example, the low frequency capacitance is about 1 nF, parasitic inductance is about 500 pH and equivalent resistance is about 1 Ω. With a conventional capacitor (curve 100) e.g. where the capacitance is relatively unchanged, the self-resonant frequency due to parasitic inductance is about 0.23 GHz. With the ferroelectric capacitor I (curve 102) where the relaxation frequency is about 0.1 GHz and varies according to the relationship defined in equation (4), the self-resonant frequency is increased to about 0.53 GHz for the same low frequency capacitances. It is also possible to use a much larger capacitance of about 0.8 nF in ferroelectric capacitor II (curve 104) with a relaxation frequency of about 0.02 GHz whilst still achieving an improved self-resonant frequency of about 0.36 GHz. These examples illustrate the concept of extending the power decoupling bandwidth according to embodiments of the present invention. In the example embodiments, the relaxation frequency is controlled to achieve power distribution design optimization by controlling the grain/particle size of the ferroelectric material used as a dielectric. In the case of hydrothermal synthesis, the grain/particle size can e.g. be controlled through process or synthesis temperature and applied pressure. In the case of matrix composite materials, the grain/particle size of powders prior to mixing or binding can e.g. be controlled through compaction techniques.

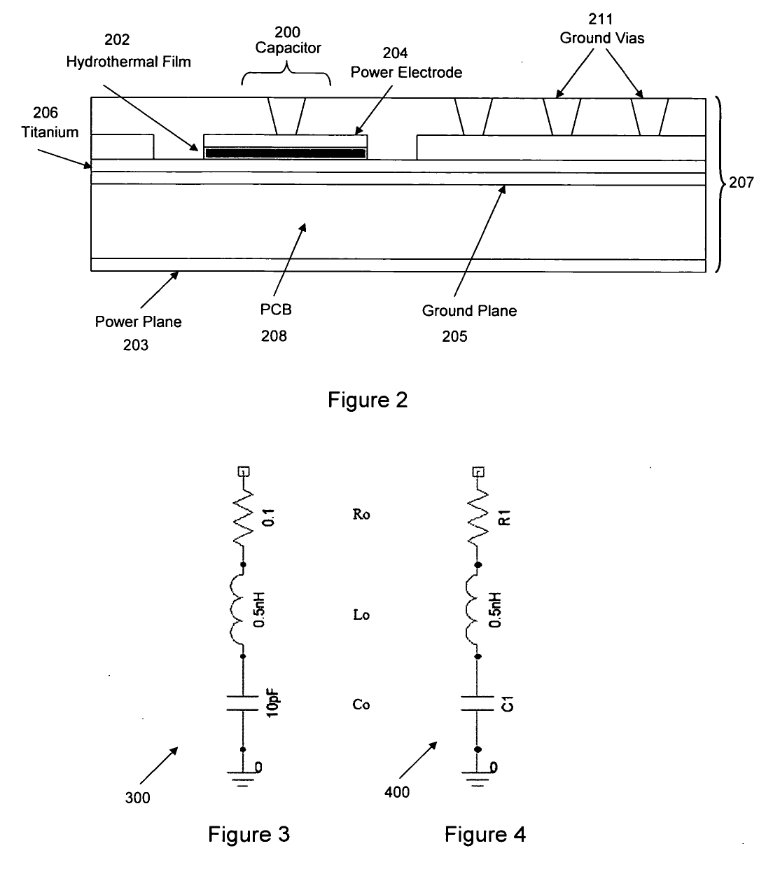

FIG. 2 illustrates an example embodiment of an application where an ultra-thin capacitor 200 is fabricated using a ferroelectric dielectric material using well established processing techniques. In this embodiment, a selective hydrothermal synthesis process is used to form an ultra-thin ferroelectric film 202 of a thickness of less than about 1 μm.

The top or power electrode 204 can be formed using, but not limited to, electroplating and printing, and can consist of highly conductive or lossy materials, depending on specific system requirements. With this approach, a controllable equivalent series resistance for the embedded capacitor can be achieved. The ground electrode 206 is also formed using, but not limited to, electroplating and printing, and consists of highly conductive materials, e.g. Titanium (Ti) in the example embodiment. The ground electrode is formed on the ground plane 205. Details of the fabrication process of the substrate structure 207 illustrated in FIG. 2 are described hereinafter.

It should be noted that in FIG. 2, the interconnection between the top or power electrode 204 and the power plane 203 has been omitted for clarity. It will be appreciated by the person skilled in the art that this interconnection may be effected by numerous known design techniques, including via-interconnections through the PCB 208. For example, ground vias 211 are formed for ground interconnection of surface mounted devices (not shown) to the ground plane 205.

FIGS. 3 and 4 show equivalent circuits for conventional power decoupling and power decoupling according to an example embodiment of the present invention, respectively.

In the conventional circuit 300, the resistance (Ro), inductance (Lo) and capacitance (Co) values are relatively constant, that is, these elements are intentionally designed to be constant with respect to frequency. The bandwidth of a power decoupling circuit is typically limited by the self resonant frequency of the power decoupling circuit in accordance with equation (2)

In the circuit 400 according to the example embodiment, both the resistance (R₁) and capacitance (C₁) values are variable. The R₁ value can be chosen to provide power decoupling resonance damping. This damping can help to suppress the impedance peak magnitude or the resultant switching noise. By using ferroelectric dielectric materials, C₁ can also be made frequency dependent according to equation (3).

In the example embodiment, the resonant frequency can thus be extended to improve the bandwidth of the power decoupling circuit.

Returning now to the example embodiment of FIG. 2, the substrate structure 207 for power decoupling is designed and fabricated using hydrothermally synthesized capacitor films to form capacitors, and integrated with discrete capacitors, active devices and multi-layer signal and power distribution interconnects.

A layer of titanium 206 is deposited on a printed circuit board (PCB) 208 using known methods, including, but not limited to, sputtering. Alternatively, a titanium foil may, for example, be laminated onto the PCB 208.

The hydrothermal synthesis process typically uses an aqueous or solvent solution that chemically reacts with the titanium coating to form crystalline barium titanate films. An example of the aqueous solution is Ba(OH)₂. With improved chemical reaction, e.g. by increasing the processing temperature, precursor selection or microwave assisted techniques, the film densification can be improved along with reduced grain size.

By using a selective area hydrothermal synthesis process, the hydrothermal film 202 can be grown to form an ultrathin capacitor film layer 202. To ensure low temperature fabrication compatibility typically below 300° C. with an inherently organic material composition of the PCB 208, thin-film porosity is prevalent in the hydrothermally synthesized dielectric film 202.

Typically, the seed layer (not shown) for the top or power electrode 204 is sputtered and, due to the thin-film 202 porosity, the top or power electrode 204 may be shorted to the ground plane 210. Embodiments of the present invention avoid such shorting as a result of using the hydrothermally synthesized dielectric film 202 that exhibits thin-film porosity.

In a first example method, the top or power electrode 204 is deposited on the hydrothermal film 202 using thick-film techniques, including, but not limited to, printing, jetting, etc. Since thick-film techniques such as printing involve the deposition of larger sized particles, shorting of the top or power electrode 204 and the ground plane 210 due to the porosity of the thin-film 202 can be avoided. In addition to creating a more robust capacitor structure 200, the use of thick-film techniques also enables the use of materials to form the top or power electrode 204 that are different from those used to form the ground plane 210, i.e. materials that are different from materials which may be deposited using thin-film techniques, in the example embodiment. This method may also include the use of resistive electrode materials to achieve a desired value of equivalent series resistance without consuming additional surface area, which may otherwise be required for e.g. surface mounted discrete resistors. This approach may also maintain the requirement of low temperature processing when using low-temperature thick-film techniques such as, but not limited to, printing.

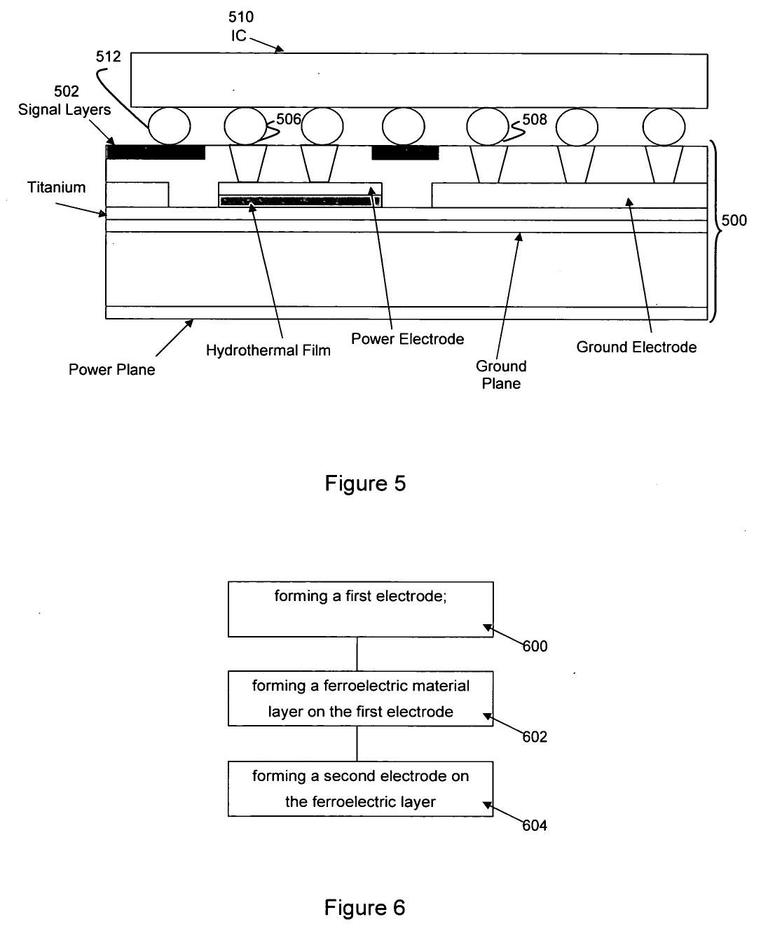

FIG. 5 shows the integration of a substrate structure 500 of the type of substrate stucture 200 (FIG. 2) with multi-layer signal interconnects, e.g. signal layer 502, power distribution interconnects, e.g. solder ball connections 506, 508, as well as interconnects to an active device in the form of an IC 510, e.g. solder ball connections 512.

FIG. 6 shows a flow chart illustrating a method of forming a substrate structure for wideband power decoupling according to an example embodiment. At step 600, a first electrode is formed. At step 602, a ferroelectric material layer is formed on the first electrode. At step 604, a second electrode is formed on the ferroelectric material layer; wherein the first electrode, the second electrode and the ferroelectric material layer form an embedded capacitor in the substrate structure.

Advantages of example embodiments described herein before over existing techniques and designs may include:
Utilization of ferroelectric characteristics to extend the operating bandwidth of power decoupling
Improved utilization of controllable relaxation frequency
Low impedance is maintained at low frequencies whilst reducing effective inductance at higher frequencies
Higher self-resonant frequency
Integration with damping electrode
High-density embedded capacitor integration
Manufacturing compatibility with existing PCB fabrication processes
Improved manufacturing yield
Improved power decoupling performance
Improved power decoupling system design flexibility
Improved power decoupling system integration with active and passive devices

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

For example, it will be appreciated that different deposition techniques at different processing temperatures may be utilised in the fabrication of the embedded capacitors, including, but not limited to, thick-film material processing or laminates. Capacitors formed with thick-film material processing or laminates may be of a thickness of about 1 μm to about 20 μm.

1. A substrate structure for wideband power decoupling comprising one or more embedded capacitors each comprising a ferroelectric material.

2. The substrate structure as claimed in claim 1, wherein the capacitors comprise an ultra-thin film of the ferroelectric material of a thickness of less than about 1 μm.

3. The substrate structure as claimed in claim 2, wherein the capacitors comprise a film of the of the ferroelectric material formed with thick-film material processing or laminates of a thickness of about 1 μm and 20 μm.

4. The substrate structure as claimed in claim 1, wherein properties of the respective ferroelectric materials are selected such that said respective ferroelectric materials exhibit desired relaxation frequencies.

5. The substrate structure as claimed in claim 1, wherein respective capacitors each comprise one or more electrodes of resistive material.

6. The substrate structure as claimed in claim 4, wherein the materials of the electrodes are selected such that the substrate structure exhibits a desired power decoupling resonance damping property.

7. The substrate structure as claimed in claim 1, further comprising multi-layer interconnects for signal and power distribution.

8. The substrate structure as claimed in claim 1, further comprising one or more discrete capacitors.

9. The substrate structure as claimed in claim 1, further comprising one or more active devices and one or more interconnects to the respective active devices.

10. The substrate structure as claimed in claim 1, wherein one or more electrodes of the capacitors are electrically connected to a power plane of the substrate structure.

11. The substrate structure as claimed in claim 1, wherein one or more electrodes of the capacitors are electrically connected to a ground plane of the substrate structure.

12. A substrate structure for wideband power decoupling comprising one or more embedded capacitors each comprising:
a ground electrode;
a power electrode; and
a ferroelectric material layer between the ground and power electrodes.

13. A method of forming a substrate structure for wideband power decoupling, the method comprising forming one or more embedded capacitors in the substrate structure, wherein each capacitor comprises a ferroelectric material.

14. The method as claimed in claim 13, wherein the capacitors are formed with an ultra-thin film of the ferroelectric material of a thickness less than about 1 μm.

15. The method as claimed in claim 13, wherein the capacitors are formed with a film of the ferroelectric material formed with thick-film material processing or laminates of a thickness of about 1 μm to 20 μm.

16. The method as claimed in claim 13, wherein properties of the respective ferroelectric materials are selected such that said respective ferroelectric materials exhibit desired relaxation frequencies.

17. The method as claimed in claim 13, wherein respective capacitors are each formed with one or more resistive material electrodes.

18. The method as claimed in claim 17, wherein the materials of the electrodes are selected such that the substrate structure exhibits a desired power decoupling frequency damping property.

19. The method as claimed in claim 13, further comprising forming multi-layer interconnects of the substrate structure for signal and power distribution.

20. The method as claimed in claim 13, further comprising providing one or more discrete capacitors as part of the substrate structure.

21. The method as claimed in claim 13, wherein the ferroelectric material is deposited utilising hydrothermal synthesis.

22. The method as claimed in claim 13, wherein electrodes of the capacitors are formed utilising thin-film processes.

23. The method as claimed in claim 13, wherein electrodes of the capacitors are formed utilising thick-film processes.

24. The method as claimed in claim 23, wherein a first electrode of the respective capacitors is formed utilising thin-film processes, and a second electrode of the respective capacitors is formed utilising thick-film processes.

25. The method as claimed in claim 13, further comprising a processing step for increasing a robustness of the as-formed ferroelectric material.

26. The method as claimed in claim 25, wherein the processing step comprises post deposition plasma processing, thick-film processing, or both.

27. A method of forming a substrate structure for wideband power decoupling, the method comprising:
forming a first electrode;
forming a ferroelectric material layer on the first electrode; and
forming a second electrode on the ferroelectric layer;
wherein the first electrode, the second electrode and the ferroelectric material layer form an embedded capacitor in the substrate structure.
